(19) United States
(12) Patent Application Publication
(10) Pub. No.: US 2017/0205447 A1
(43) Pub. Date: Jul. 20, 2017

(54) CURRENT SENSOR

(71) Applicant: ROHM CO., LTD., Kyoto (JP)

(72) Inventor: Koji SAITO, Kyoto (JP)

(21) Appl. No.: 15/405,372

(22) Filed: Jan. 13, 2017

(30) Foreign Application Priority Data
Jan. 20, 2016 (JP) 2016008965

(51) Int. Cl. G01R 15/20; G01R 19/00; G01R 1/30; G01R 33/06

(52) U.S. Cl. CPC G01R 15/20; G01R 33/063; G01R 19/0092; G01R 1/30

(57) ABSTRACT

A current sensor includes first to third magneto-impedance (MI) sensor parts, a first sample/hold part configured to receive a differential input between a first sensor signal generated by the first MI sensor part and a second sensor signal generated by the second MI sensor part to generate a first sample/hold signal, a second sample/hold part configured to receive a third sensor signal generated by the third MI sensor part to generate a second sample/hold signal, first and second amplifier parts configured to amplify the first and second sample/hold signals with first and second gains to generate first and second amplified signals, respectively, a subtraction part configured to subtract the second amplified signal from the first amplified signal to generate an output signal, and a gain adjusting part configured to adjust the first and second gains to correct a difference in sensitivity of the first and second MI sensor parts.

### CROSS-REFERENCE TO RELATED APPLICATION

This application is based upon and claims the benefit of priority from Japanese Patent Application No.2016-008965, filed on Jan. 20, 2016, the entire contents of which are incorporated herein by reference.

### TECHNICAL FIELD

The present disclosure relates to a current sensor.

### BACKGROUND

Conventionally, a current sensor using a hall element (i.e., a hall type) or a current sensor using a magneto-resistance effect element (i.e., an MR type) has been known as a current sensor capable of measuring a current flowing through a primary conductor while securing insulation from the primary conductor.

However, since the hall-type current sensor generally has low sensitivity, the distance between the primary conductor and the current sensor should be close to each other, which causes a problem lowering an insulating property. Further, the sensitivity may be increased using a magnetic core such as a magnetic collecting yoke or the like, but such a conventional method increases the cost and the size of the current sensor. In addition, when the magnetic core is used, the magnetic core may be easily affected by an ambient magnetic field serving as disturbance. In this case, a magnetic shield should be prepared depending on an installation position of the current sensor, which increases the cost and the size of the current sensor.

Meanwhile, since the MR-type current sensor has sensitivity higher than that of the hall-type current sensor, it is not necessary to use the magnetic core. However, the MR-type current sensor requires an application means (e.g., a permanent magnet) of a bias magnetic field, which needs to be further improved in terms of reduction in the cost and size of the current sensor.

Further, Patent a magneto-impedance (MI)-type magnetic measurement device using a magnetic impedance effect element has been proposed, but an application of a current sensor has not been disclosed. Moreover, there is also a room for improvement in a method of correcting a difference in sensitivity of a pair of MI sensors.

### SUMMARY

The present disclosure provides some embodiments of a compact current sensor with high precision at low costs.

According to one embodiment of the present disclosure, there is provided a current sensor, including: a first magneto-impedance (MI) sensor part and a second MI sensor part arranged to apply magnetic fields induced by a measurement target current in mutually opposite directions; a third MI sensor part arranged to be incapable of detecting the magnetic fields induced by the measurement target current; a first sample/hold part configured to receive a differential input between a first sensor signal generated by the first MI sensor part and a second sensor signal generated by the second MI sensor part to generate a first sample/hold signal; a second sample/hold part configured to receive a third sensor signal generated by the third MI sensor part to generate a second sample/hold signal; a first amplifier part configured to amplify the first sample/hold signal or an amplified signal of the first sample/hold signal with a first gain to generate a first amplified signal; a second amplifier part configured to amplify the second sample/hold signal or an amplified signal of the second sample/hold signal with a second gain to generate a second amplified signal; a subtraction part configured to subtract the second amplified signal from the first amplified signal to generate an output signal; and a gain adjusting part configured to adjust the first gain and the second gain to correct a difference in sensitivity of the first MI sensor part and the second MI sensor part (first configuration).

In the current sensor having the first configuration, the first to third MI sensor parts may be arranged in series on a sensor device in order of the first MI sensor part, the third MI sensor part, and the second MI sensor part (second configuration).

In the current sensor having the first or second configuration, the gain adjusting part may be configured to hold adjusted values of the first gain and the second gain in a non-volatile manner (third configuration).

In the current sensor having any one of the first to third configurations, when the sensitivities of the first to third MI sensor parts are α, β and γ, respectively, and the first gain and the second gain are X and Y, respectively, it may be established that X/Y=γ/(α−β) (fourth configuration).

In the current sensor having the fourth configuration, it may be established that X=2/(α+β) and Y={2·(α−β)}/{(α+β)·γ} fifth configuration).

In the current sensor having any one of the first to fifth configurations, the first to third MI sensor parts may include magneto-impedance effect elements and coils, respectively, and is configured to output induced voltages of the coils as the first to third sensor signals (sixth configuration).

In the current sensor having the sixth configuration, the first to third MI sensor parts may share a single magneto-impedance effect element (seventh configuration).

In the current sensor having the sixth or seventh configuration, the magnetic impedance effect element may be an amorphous wire (eighth configuration).

In the current sensor having any one of the sixth to eighth configurations, when the numbers of turns of the respective coils of the first to third MI sensor parts are m1, m2 and m3, it may be established that m1=m2>m3 (ninth configuration).

According to another embodiment of the present disclosure, there is provided a current sensor, including: a first MI sensor part and a second MI sensor part arranged to apply magnetic fields induced by a measurement target current in mutually opposite directions; a sample/hold part configured to receive a differential input between a first sensor signal generated by the first MI sensor part and a second sensor signal generated by the second MI sensor part to generate a sample/hold signal; and an amplifier part configured to amplify the sample/hold signal to generate an output signal (tenth configuration).

According to still another embodiment of the present disclosure, there is provided a current sensor, including: a first MI sensor part and a second MI sensor part arranged to apply magnetic fields induced by a measurement target current in mutually opposite directions; a first sample/hold part configured to receive a first sensor signal generated by the first MI sensor part to generate a first sample/hold signal; a second sample/hold part configured to receive a second sensor signal generated by the second MI sensor part to generate a second sample/hold signal; a first amplifier part configured to amplify the first sample/hold signal or an amplified signal of the first sample/hold signal with a first gain to generate a first amplified signal; a second amplifier part configured to amplify the second sample/hold signal or an amplified signal of the second sample/hold signal with a second gain to generate a second amplified signal; a subtraction part configured to subtract the second amplified signal from the first amplified signal to generate an output signal; and a gain adjusting part configured to adjust the first gain and the second gain to correct a difference in sensitivity of the first MI sensor part and the second MI sensor part (eleventh configuration).

In the current sensor having the eleventh configuration, when the sensitivity of the first MI sensor part and the sensitivity of the second MI sensor part are α and β, respectively, and the first gain and the second gain are X and Y, respectively, it may be established that X/Y=β/α (twelfth configuration).

In the current sensor having the twelfth configuration, it is established that X=1/α and Y=1/β (thirteenth configuration).

According to a further embodiment of the present disclosure, there is provided a measurement target system, the system including: a primary conductor; and the current sensor having any one of the first to thirteenth configurations, configured to measure a measurement target current flowing through the primary conductor while securing insulation from the primary conductor (fourteenth confirmation).

In the system having the fourteenth configuration, the primary conductor may include an outward path part and a return path part installed such that the measurement target current flows in mutually opposite directions, and the current sensor may include a sensor device installed at a position equidistant from the outward path part and the return path part to detect magnetic fields induced by the measurement target current (fifteenth configuration).

### BRIEF DESCRIPTION OF THE DRAWINGS

FIG. 1 is a schematic view illustrating an example of a measurement target system to which a current sensor is applied.

FIG. 2 is a view illustrating an arrangement example of the current sensor.

FIG. 3 is a block diagram illustrating a first embodiment of the current sensor.

FIG. 4 is a block diagram illustrating a specific example of each signal level in the first embodiment.

FIG. 5 is a block diagram illustrating a modification of the first embodiment.

FIG. 6 is a block diagram illustrating a second embodiment of the current sensor.

FIG. 7 is a block diagram illustrating a specific example of each signal level in the second embodiment.

FIG. 8 is a block diagram illustrating a third embodiment of the current sensor.

### DETAILED DESCRIPTION

Embodiments of the present disclosure will now be described with reference to the drawings.

### <Measurement Target System>

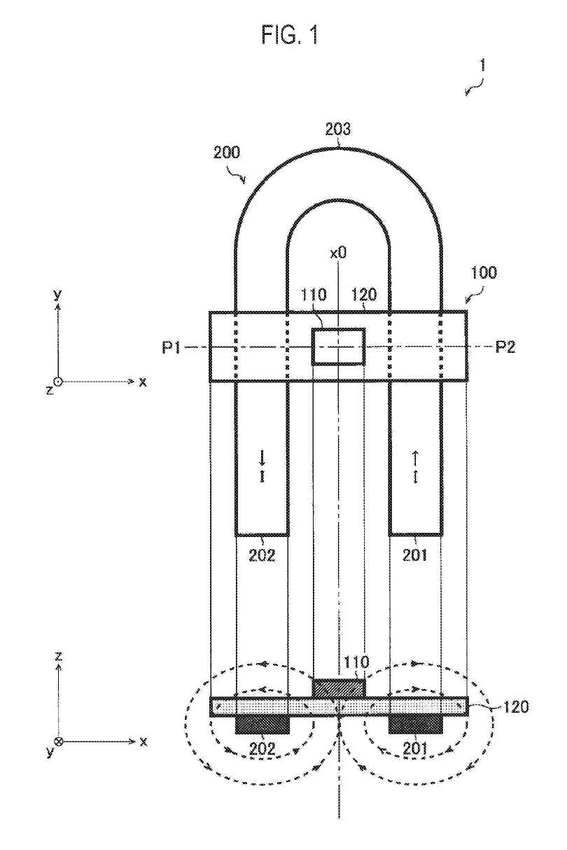

FIG. 1 is a schematic view illustrating an example of a measurement target system to which a current sensor is applied. Further, in FIG. 1, a plan view (x-y plane) of the measurement target system 1 is illustrated in an upper portion, and a cross-sectional view taken along line a P1-P2 (x-z plane) of the upper portion is illustrated in a lower portion. As illustrated in FIG. 1, the measurement target system 1 of the present configuration example includes a current sensor 100 and a primary conductor 200.

The current sensor 100 includes a sensor device 101 and a sensor substrate 120 on which the sensor device 110 is mounted, and measures a measurement target current I flowing through the primary conductor 200 while securing insulation from the primary conductor 200.

The primary conductor 200 is a current path through which the measurement target current I flows. In the example of this drawing, the primary conductor 200 includes an outward path part 201 and a return path part 202, which are installed in parallel with respect to the y axis, and a connection part 203 for connecting both. In the plan view, the primary conductor 200 is installed to have a U shape.

In the example of this drawing, the measurement target current I flows in a positive direction of the y axis through the outward path part 201, is reversed in a direction by 180° through the connection part 203, and subsequently flows out in a negative direction of the y axis through the return path part 202. In this manner, the outward path part 201 and the return path part 202 are installed to allow the measurement target current I to flow in mutually opposite directions.

The direction of the measurement target current I may also be reversed (the return path part 202→connection part 203→outward path part 201). Further, the connection part 203 may not necessarily be positioned at the shortest path connecting the outward path part 201 and the return path part 202, and for example, the connection part 203 may be freely extended toward a load or bypassed to avoid an obstacle.

In the plan view, the sensor substrate 120 is an elongated rectangular plate member of which a longitudinal direction is an x-axis direction, and in the example of FIG. 1, the sensor substrate 120 is disposed to be equally distanced from both the outward path part 201 and the return path part 202 horizontally. Further, a rear side of the sensor substrate 120 is insulated from the outward path part 201 and the return path part 202. However, the contact/non-contact of the outward path part 201 and the return path part 202 from the rear side of the sensor substrate 120 does not matter.

The sensor device 110 is installed on a surface of the sensor substrate 120 to be centered at a center position x0 of the sensor substrate 120 in a longitudinal direction (i.e., a position equidistant from the outward path part 201 and the return path part 202). The sensor device 110 detects a magnetic field (see the arrows of broken lines in the lower portion of FIG. 1) induced by the measurement target current I and outputs an electric signal (e.g., a voltage signal) corresponding to a magnitude of the measurement target current I.

Further, although it is described as an example that the sensor device 110 is mounted on the surface side of the sensor substrate 120 and the primary conductor 200 is installed on the rear side of the sensor substrate 120, a positional relationship between the sensor device 110 and the primary conductor 200 with respect to the sensor substrate 120 may be reversed.

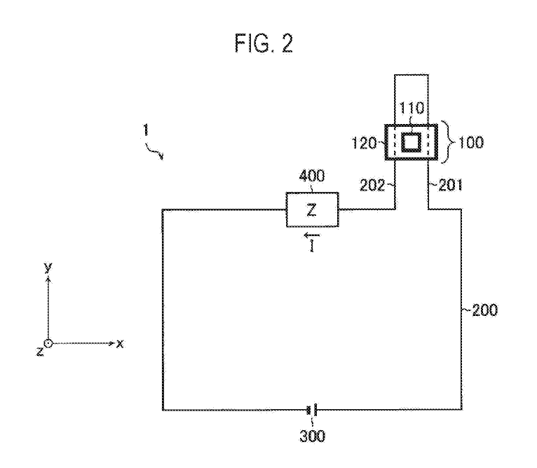

FIG. 2 is a schematic view illustrating an arrangement example of the current sensor 100. In the measurement target system 1 of FIG. 2, in order to form the outward path part 201 and the return path part 202 of the primary conductor 200, the primary conductor 200 is installed by bending a current path portion extending from a positive electrode terminal of a power source 300 to a load 400 to have a U shape. The current sensor 100 is arranged between the outward path part 201 and the return path part 202, and measures the measurement target current I flowing from the power source 300 to the load 400.

Further, the layout of the measurement target system 1 is not limited thereto, and for example, the primary conductor 200 may be installed by bending the current path part extending from the load 400 to a negative electrode terminal of the power source 300 to have a U shape. In this case, the current sensor 100 measures the measurement target current I returned from the load 400 to the power source 300.

### Current Sensor (First Embodiment)

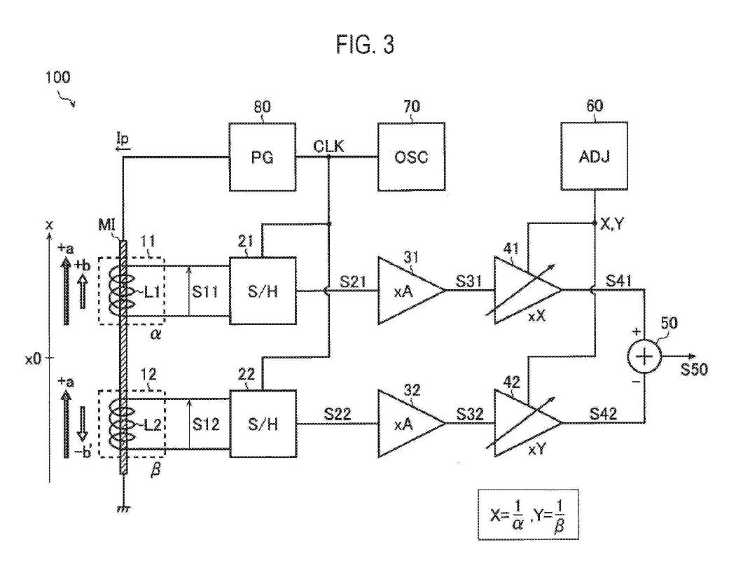

FIG. 3 is a block diagram illustrating a first embodiment of the current sensor 100. In this embodiment, the current sensor 100 includes magneto-impedance (MI) sensor parts 11 and 12, sample/hold parts 21 and 22, main amplifier parts 31 and 32, sub-amplifier parts 41 and 42, a subtraction part 50, a gain adjusting part 60, an oscillation part 70, and a pulse driving part 80. Among these components, at least the MI sensor parts 11 and 12 are embedded in the sensor device 110. Meanwhile, other components may be embedded in the sensor device 110 or installed on the sensor substrate 120.

The MI sensor parts 11 and 12 include a shared magnetic impedance effect element MI (e.g., an amorphous wire formed of a magnetic anisotropic material) and coils L1 and L2 wound around the magnetic impedance effect element MI, and output induced voltages generated between both ends of the coils L1 and L2 as sensor signals S11 and S12.

Further, the number of turns m1 of the coil L1 and the number of turns m2 of the coil L2 are equal. However, m1 and m2 may be different (i.e., m1≠m2). The MI sensor parts 11 and 12 share the single magnetic impedance effect element MI. With this configuration, it is possible to increase the pair properties of the MI sensor parts 11 and 12.

The MI sensor parts 11 and 12 are arranged in series along the x axis on the sensor device 110. More specifically, the MI sensor parts 11 and 12 are installed at positions linearly symmetrical with respect to the central position x0 of the sensor substrate 120 in the longitudinal direction (e.g., near both end portions of the sensor device 110 in the x-axis direction). Thus, in consideration of the positional relationship between the MI sensors 11 and 12 and the primary conductor 200, one of the MI sensors 11 and 12 is arranged closer to the outward path part 201 and the other is arranged closer to the return path part 202.

Due to the aforementioned sensor arrangement, magnetic fields (hereinafter, referred to as “measurement target magnetic fields”) induced by the measurement target current I are applied in mutually opposite directions to the MI sensor parts 11 and 12. In the example of FIG. 3, a measurement target magnetic field (+b) in a positive direction of the x axis is applied to the MI sensor part 11 and a measurement target magnetic field (−b′) in a negative direction of the x axis is supplied to the MI sensor part 12. That is, the measurement target magnetic fields respectively applied to the MI sensor parts 11 and 12 have mutually opposite phases (+b, −b′). Further, absolute values (b, b′) of the measurement target magnetic fields respectively applied to the MI sensor parts 11 and 12 are generally different (i.e., b≠b′) due to a position difference of the MI sensor parts 11 and 12 or the like.

Meanwhile, ambient magnetic fields serving as a disturbance may be applied to the MI sensor parts 11 and 12 depending on an environment in which the measurement target system 1 is placed. In this case, the ambient magnetic fields respectively applied to the MI sensor parts 11 and 12 are in phase (+a) with each other.

Both the sample/hold parts 21 and 22 sample/hold signal values of the sensor signals S11 and S12 in a predetermined phase in synchronization with a clock signal CLK (e.g., peak values) to generate sample/hold signals S21 and S22, respectively.

The main amplifier part 31 amplifies the sample/hold signal S21 with a fixed gain A to generate an amplified signal S31. The sub-amplifier part 41 amplifies the amplified signal S31 with a variable gain X to generate an amplified signal S41. The main amplifier part 31 and the sub-amplifier part 41 may also be integrated.

The main amplifier part 32 amplifies the sample/hold signal S22 with the fixed gain A to generate an amplified signal S32. The sub-amplifier part 42 amplifies the amplified signal S32 with a variable gain Y to generate an amplified signal S42. The main amplifier part 32 and the sub-amplifier part 42 may also be integrated.

The subtraction part 50 subtracts the amplified signal S42 from the amplified signal S41 to generate an output signal S50. By performing this subtraction processing, it is possible to obtain the output signal S50 in which the influence of the ambient magnetic field (+a) is canceled.

The gain adjusting part 60 adjusts the variable gains X and Y of the respective sub-amplifier parts 41 and 42 in order to correct a difference in sensitivity between the MI sensor parts 11 and 12. More specifically, when the sensitivities of the MI sensor parts 11 and 12 are a and β, respectively, the gain adjusting part 60 adjusts the variable gains X and Y such that X/Y=β/α(e.g., X=1/α and Y=1/β) is established. Further, the sensitivities α and β may be defined by a ratio of an actual output level to an ideal output level of the sensor signals S11 and S12, respectively.

In particular, the gain adjusting part 60 has a function of holding adjusted values of the variable gains X and Y in a non-volatile manner. With this configuration, for example, the variable gains X and Y are adjusted before the shipment of the current sensor 100, and the adjusted results are retained in the gain adjusting part 60. Thus, it is possible to enhance a detection degree of the current sensor 100. Further, in order to hold the adjusted values, a semiconductor memory such as a one-time programmable read only memory (OTPROM) or the like may be used or a technique such as laser trimming or the like may also be used.

The oscillation part 70 generates a clock signal CLK having a predetermined frequency and supplies the generated clock signal CLK to the sample/hold parts 21 and 22 and the pulse driving part 80.

The pulse driving part 80 generates a driving current Ip in the form of a pulse wave in synchronization with the clock signal CLK, and supplies the generated driving current Ip to the magneto-impedance effect element MI. When the driving current Ip flows, a transient induced voltage is generated in the coils L1 and L2 depending on the applied magnetic field due to the skin effect of the magneto-impedance effect element MI. Thus, by detecting the transient induced voltage as the sensor signals S11 and 512, it is possible to measure a strength of the measurement target magnetic field (further, a magnitude of the measurement target current I).

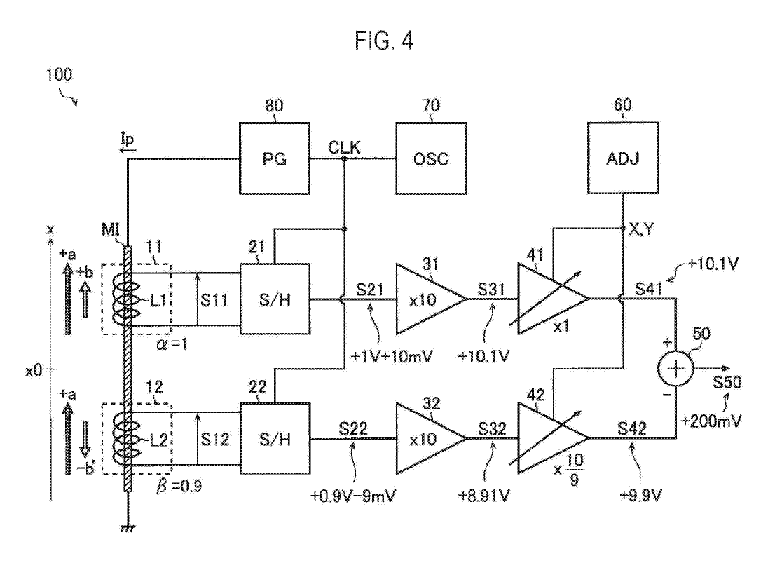

FIG. 4 is a block diagram illustrating a specific example of each signal level in the first embodiment. Hereinafter, it is assumed that α=1, β=0.9, A=10, X=1(=1/α), and Y=10/9(=1/β), and details thereof will be described. Further, a difference in sensitivity (i.e., a discrepancy between the sensitivities α and β) between the MI sensor parts 11 and 12 is substantially inevitably generated due to a position difference and a matching difference of the MI sensor parts 11 and 12. However, it is assumed that the absolute values (b, b′) of the measurement target magnetic fields respectively applied to the MI sensor parts 11 and 12 are set to be b=b′ for ease of understanding.

In the example of FIG. 4, the signal level of the sample/hold signal S21 becomes a voltage value (=+1.01 V) as the sum of a voltage value (=+1 V) induced by the ambient magnetic field (+a) and a voltage value (=+10 mV) induced by the measurement target magnetic field (+b). Since the main amplifier part 31 amplifies the sample/hold signal S21 by 10 times and outputs the same, the signal level of the amplified signal S31 becomes +10.1 V. Further, since the sub-amplifier part 41 outputs the amplified signal S31 at the same magnification (one time), a signal level of the amplified signal S41 becomes +10.1 V.

Meanwhile, the signal level of the sample/hold signal S22 is a voltage value (=+0.891 V) as the sum of a voltage value (=+0.9 V (=+1 V×0.9)) induced by the ambient magnetic field (+a) and a voltage value (=−9 mV (=−10 mV×0.9)) induced by the measurement target magnetic field (−b′). In this manner, when the sensitivity β of the MI sensor part 12 is not 1, the signal level of the sample/hold signal S22 deviates from an ideal value (=+0.99 V (=+1 V−10 mV)). Since the main amplifier part 32 amplifies the sample/hold signal S22 by 10 times and outputs the same, the signal level of the amplified signal S32 becomes +8.91 V. Further, since the sub-amplifier part 42 amplifies the amplified signal S32 by 1.11 times (=10/9 times) and outputs the same, the signal level of the amplified signal S42 becomes +9.9 V. In this manner, through the amplification processing by the sub-amplifier part 41, the signal level of the amplified signal S42 is corrected to the ideal value (=+0.99 V×10).

The subtraction part 50 subtracts the amplified signal S42 from the amplified signal S41 to generate an output signal S50. Thus, the signal level of the output signal S50 becomes +200 mV (=0.2 V). This voltage value is equal to a voltage obtained by decoupling the voltage value (=±10 mV) induced by the measurement target magnetic field (±b) with the fixed gain A and further doubling it through differential amplification.

In this manner, since the current sensor 100 of this embodiment has very high sensitivity, relative to the hall type current sensor, it is possible to measure a current even at a position sufficiently away from the primary conductor 200 without using a magnetic core. Further, unlike the MR-type current sensor, the current sensor 100 does not require a bias magnetic field application means (i.e., a permanent magnet).

In addition, the current sensor 100 of this embodiment can easily correct a difference in sensitivity between the MI sensor parts 11 and 12 by simply individually adjusting the variable gains X and Y of the sub-amplifier parts 41 and 42, without installing a separate adjusting member (magnetic substance, a magnet, a conductor, a coil, etc.) near the MI sensor parts 11 and 12 or without installing a mechanical mechanism for relatively changing orientations of both of the MI sensor parts 11 and 12. Thus, it is possible to measure a current with high accuracy without increasing the cost and size of the current sensor 100 and by canceling the influence of the ambient magnetic field (+a).

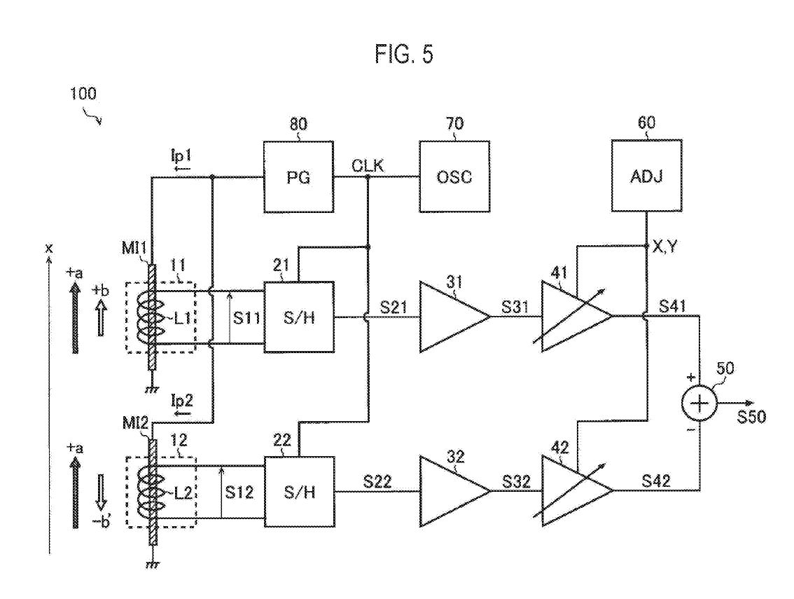

FIG. 5 is a block diagram illustrating a modification of the first embodiment. In the current sensor 100 of this modification, the MI sensor parts 11 and 12 have independent magneto-impedance effect elements MI1 and MI2, respectively. Driving currents Ip1 and Ip2 having a pulse waveform are supplied to these magnetic impedance effect elements MI1 and MI2, respectively. When this modification is employed, a degree of freedom of an arrangement layout of the MI sensor parts 11 and 12 can be increased. However, as mentioned above, when the enhancement of the pair properties of the MI sensor parts 11 and 12 are prioritized, it is desirable to employ the configuration of FIG. 1.

Further, in the current sensor 100 of the aforementioned first embodiment, when the relatively large ambient magnetic field (+a) is applied, the amplified signals S31 and S32 or the amplified signals S41 and S42 may be excessive to deviate from an input dynamic range of the subtraction part 50 (for example, see FIG. 4). Thus, since the fixed gain A of the main amplifier parts 31 and 32 should be lowered in advance depending on a usage environment in some cases, there is a concern that the SN ratio will deteriorate. A method for eliminating such concern will be proposed below.

### Current Sensor (Second Embodiment)

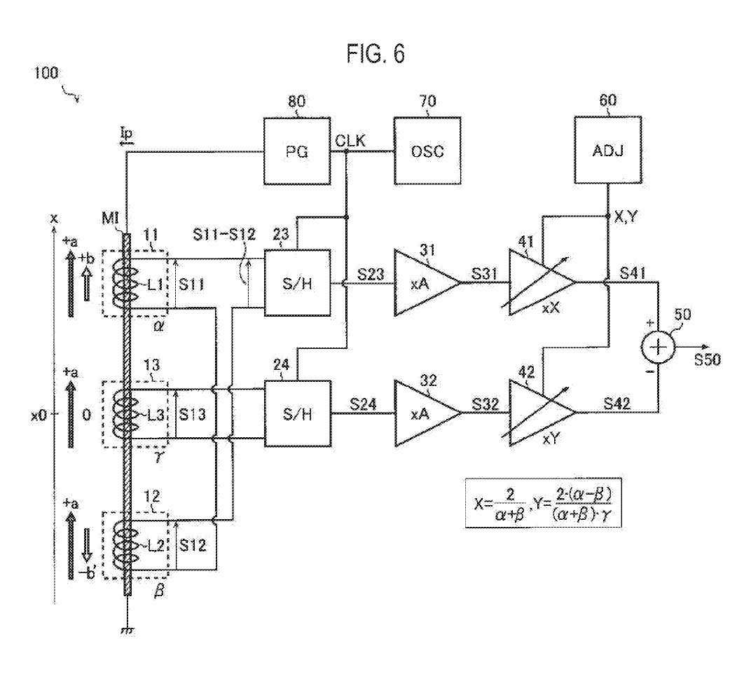

FIG. 6 is a block diagram illustrating a second embodiment of the current sensor 100. The current sensor 100 of the second embodiment is characterized in that it is based on the first embodiment, and includes a third MI sensor part 13, in addition to the MI sensors 11 and 12, and also includes sample/hold parts 23 and 24 instead of the sample/hold parts 21 and 22. Therefore, duplicate description will be omitted by denoting the same components as those of the first embodiment with the same reference numerals as those of FIG. 3. Hereinafter, the characteristic parts of the second embodiment will be mainly described.

The MI sensor part 13 includes a magneto-impedance effect element MI shared by the MI sensor parts 11 to 13, and a coil L3 wound around the magneto-impedance effect element MI, and outputs an induced voltage generated between both ends of the coil L3 as the sensor signal S13.

Further, the number of turns m3 of the coil L3 is set smaller than the numbers of turns m1 and m3 of the coils L1 and L2 (where m1=m2>m3). With this configuration, it becomes possible to set the sensitivity y of the MI sensor part 13 to be intentionally smaller than the sensitivities α and β of the MI sensor parts 11 and 12, and further to easily adjust a gain as will be described later. However, the number of turns m3 may be set equal to the numbers of turns m1 and m2.

Further, the MI sensor parts 11 to 13 are arranged in series on the sensor device 110 along the x axis in order of the MI sensor part 11, the MI sensor part 13 and the second MI sensor part 12. Specifically, the MI sensor part 13 is installed at the center position x0 of the sensor substrate 120 in a longitudinal direction. Thus, in consideration of a positional relationship between the MI sensor part 13 and the primary conductor 200, the MI sensor part 13 is arranged at a position equidistant from both the outward path part 201 and the return path part 202 and is arranged at a position where the measurement target magnetic field is not detected (more accurately, a position where the measurement target magnetic field applied from the outward path part 201 and the measurement target magnetic field applied from the return path part 202 cancel each other so as not to be substantially influenced)

Meanwhile, similar to the MI sensor parts 11 and 12, an ambient magnetic field serving as a disturbance may be applied to the MI sensor part 13 depending on an environment in which the measurement target system 1 is placed. In this case, the ambient magnetic fields respectively applied to the MI sensor parts 11 to 13 are all in phase (+a).

The sample/hold part 23 receives a differential input between the sensor signals S11 and S12, and samples/holds a signal value (e.g., a peak value) of a differential sensor signal (=S11-S12) in a predetermined phase in synchronization with a clock signal CLK to generate a sample/hold signal S23.

The sample/hold part 24 samples/holds a signal value (e.g., a peak value) of a sensor signal S13 in a predetermined phase in synchronization with the clock signal CLK to generate a sample/hold signal S24.

The main amplifier part 31 amplifies the sample/hold signal S23 with the fixed gain A to generate an amplified signal S31. The sub-amplifier part 41 amplifies the amplified signal S32 with the variable gain Y to generate an amplified signal S41. The main amplifier part 32 and the sub-amplifier part 42 may also be integrated.

The main amplifier part 32 amplifies the sample/hold signal S24 with the fixed gain A to generate an amplified signal S32. The sub-amplifier part 42 amplifies the amplified signal S32 with the variable gain Y to generate an amplified signal S42. The main amplifier part 32 and the sub-amplifier part 42 may also be integrated.

The gain adjusting part 60 adjusts the variable gains X and Y of the respective sub-amplifier parts 41 and 42 in order to correct a difference in sensitivity of the MI sensor parts 11 and 12. Specifically, when the sensitivities of the MI sensor parts 11 to 13 are α, β and γ, respectively, the gain adjusting part 60 adjusts the variable gains X and Y such that X/Y=γ/(α−β) is established (e.g., X=2/(α+β) and Y={2·(α−β)}/{(αβ)·γ}). Further, the sensitivity y of the MI sensor part 13 may be defined by a ratio of an actual output level of the sensor signal S13 to an ideal output level of the sensor signals S11 and S12.

When the ratio of X/Y is determined as described above, a difference in detection of the ambient magnetic field (+a) resulting from the difference in sensitivity of the coils L1 and L2 may be canceled out (details thereof will be described later). Further, the ratio of X/Y is not changed even though there is a difference in strength (+b-b′) of the measurement target magnetic fields.

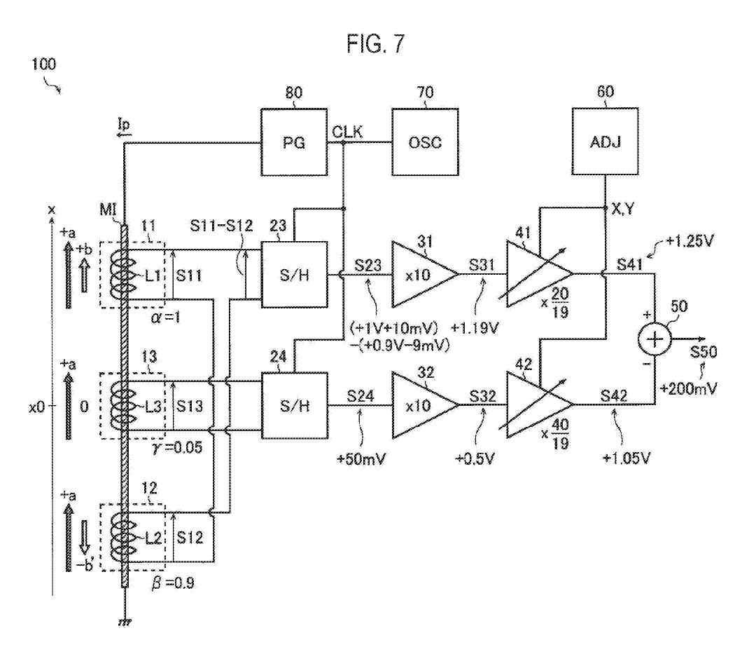

FIG. 7 is a block diagram illustrating a specific example of each signal level in the second embodiment. Hereinafter, it is assumed that α=1, β=0. 9, γ=0.05, A=10, X=20/19(=2/(α+β) and Y=40/19(={2·(α−β)}/{(α+β)·γ}), and details thereof will be described. Further, it is assumed that the absolute values (b, b′) of the measurement target magnetic fields respectively applied to the MI sensor parts 11 and 12 are set to be b=b′ for ease of understanding.

In the example of FIG. 7, the signal level of the sample/hold signal S23 becomes a voltage value (=0.119 V) obtained by subtracting a signal value (=0.9 V−9 mV) of the sensor signal S12 in the same phase from a signal value (=+1 V+10 mV) of the sensor signal S11 in a predetermined phase. Since the main amplifier part 31 amplifies the sample/hold signal S23 by 10 times and outputs the same, the signal level of the amplified signal S31 becomes +1.19 V. Further, since the sub-amplifier part 41 amplifies the amplified signal S31 by 1.053 times (=20/19 times) and outputs the same, the signal level of the amplified signal S41 becomes +1.25 V (2A·{(α−β)/(α+β)}·a+2A·b).

In this manner, in the current sensor 100 of this embodiment, since the sensor signals S11 and S12 are differentiated at a front stage of the main amplifier part 31, even when a relatively large ambient magnetic field (+a) is applied, the amplified signals S31 and S41 are not excessive (for example, see FIG. 7). More specifically, in the second embodiment (FIG. 7), the signal level of the amplified signal S31 is +1.19 V, and the signal level can be reduced to about 1/10 while the signal level of the amplified signal S31 is +10.1 V in the aforementioned first embodiment (FIG. 4). Thus, since there is no need to lower the fixed gain A of the main amplifier part 31 in advance, the SN ratio is not degraded.

Meanwhile, the signal level of the sample/hold signal S24 has a voltage value (=+50 mV (=+1 V×0.05) induced by only the ambient magnetic field (+a). Since the main amplifier part 32 amplifies the sample/hold signal S24 by 10 times and outputs the same, the signal level of the amplified signal S32 becomes +0.5 V. Further, since the sub-amplifier part 42 amplifies the amplified signal S32 by 2.105 times (=40/19 times) and outputs the same, the signal level of the amplified signal S42 becomes +1.05 V(=2A·{(α−β)/(α+β)}·a).

The subtraction part 50 subtracts the amplified signal S42 from the amplified signal S41 to generate an output signal S50. Thus, the signal level of the output signal S50 becomes +200 mV (=2A·b). This voltage value is equal to a voltage obtained by decoupling the voltage value (=±10 mV) induced by the measurement target magnetic field (±b) by the fixed gain A and further doubling it through differential amplification.

In this manner, similar to the aforementioned first embodiment, according to the current sensor 100 of this embodiment, it is possible to measure a current with high accuracy without increasing the cost and size of the current sensor 100 and by canceling the influence of the ambient magnetic field (+a).

Furthermore, as mentioned above, the sensitivity γ of the MI sensor part 13 for detecting only the ambient magnetic field (+a) is set smaller than the sensitivities α and β of the MI sensor parts 11 and 12. Thus, even though the gain of the main amplifier part 32 is set equal to the gain of the main amplifier part 31 (=fixed gain A), the amplified signals S32 and S42 are not excessive. However, the sensitivity γ does not need to be necessarily set smaller than the sensitivities α and 62 , but it may be γ=0.5 or γ=1. For example, in the example of this drawing, when γ=1, the main amplifier part 32 may be omitted and the gains of the sub-amplifier parts 41 and 42 may be adjusted such that X/Y=10.

### Current Sensor (Third Embodiment)

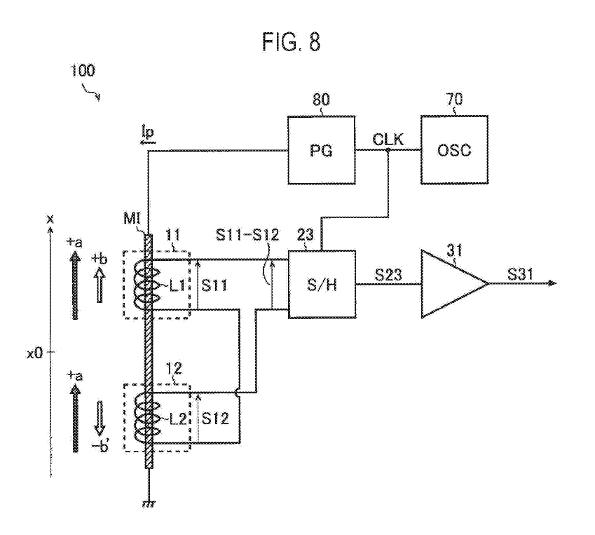

FIG. 8 is a block diagram illustrating a third embodiment of the current sensor 100. This embodiment is based on the second embodiment (FIG. 6) and is configured such that the MI sensor part 13, the sample/hold part 24, the main amplifier part 32, the sub-amplifier parts 41 and 42, the subtraction part 50, and the gain adjusting part 60 are omitted and the amplified signal S31 is a final output signal.

That is, the current sensor 100 of this embodiment is implemented by extracting only a technical concept that the sensor signals S11 and S12 are differentiated at a front stage of the main amplifier part 31, from the second embodiment.

With this configuration, similar to the second embodiment, even when a relatively large ambient magnetic field (+a) is applied, the amplified signal S31 becomes not excessive. Thus, since there is no need to lower the fixed gain A of the main amplifier part 31 in advance, the SN ratio is not degraded. However, as the MI sensor part 13 or the like is omitted, it is impossible to correct a difference in sensitivity between the MI sensor parts 11 and 12. Accordingly, it should be noted that there is a need to reduce a difference in sensitivity itself

### Other Embodiments

Further, various technical features described herein may be differently modified, in addition to the aforementioned embodiments, without departing from the spirit of the present disclosure. That is, the aforementioned embodiments are merely illustrative for all the purposes and should not be understood as limiting. The technical scope of the present disclosure is presented by the accompanying claims, rather than the description of the embodiments, and thus intended to include all modifications that are within the accompanying claims and their equivalents.

The current sensor described herein can be widely utilized in all systems (such as a photovoltaic power generation system) in which it is necessary to measure a current flowing through a primary conductor while securing insulation from the primary conductor.

According to some embodiments of the present disclosure, it is possible to provide a compact current sensor with high precision at low costs.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A current sensor, comprising:
a first magneto-impedance (MI) sensor part and a second MI sensor part arranged to apply magnetic fields induced by a measurement target current in mutually opposite directions;
a third MI sensor part arranged to detect the magnetic fields induced by the measurement target current;
a first sample/hold part configured to receive a differential input between a first sensor signal generated by the first MI sensor part and a second sensor signal generated by the second MI sensor part to generate a first sample/hold signal;
a second sample/hold part configured to receive a third sensor signal generated by the third MI sensor part to generate a second sample/hold signal;
a first amplifier part configured to amplify the first sample/hold signal or an amplified signal of the first sample/hold signal with a first gain to generate a first amplified signal;
a second amplifier part configured to amplify the second sample/hold signal or an amplified signal of the second sample/hold signal with a second gain to generate a second amplified signal;
a subtraction part configured to subtract the second amplified signal from the first amplified signal to generate an output signal; and
a gain adjusting part configured to adjust the first gain and the second gain to correct a difference in sensitivity of the first MI sensor part and the second MI sensor part.

2. The current sensor of claim 1, wherein the first to third MI sensor parts are arranged in series on a sensor device in order of the first MI sensor part, the third MI sensor part and the second MI sensor part.

3. The current sensor of claim 1, wherein the gain adjusting part is configured to hold adjusted values of the first gain and the second gain in a non-volatile manner.

4. The current sensor of claim 1, wherein when sensitivities of the first to third MI sensor parts are α, β and γ, respectively, and the first gain and the second gain are X and Y, respectively, it is established that X/Y=γ/(α−β).

5. The current sensor of claim 4, wherein it is established that X=2/(α+β) and Y={2·(α−β)}/{(α+β)·γ}.

6. The current sensor of claim 1, wherein the first to third MI sensor parts include magneto-impedance effect elements and coils, respectively, and are configured to output induced voltages of the coils as the first to third sensor signals, respectively.

7. The current sensor of claim 6, wherein the first to third MI sensor parts share a single magneto-impedance effect element.

8. The current sensor of claim 6, wherein the magneto-impedance effect elements are an amorphous wire.

9. The current sensor of claim 6, wherein when the numbers of turns of the respective coils of the first to third MI sensor parts are m1, m2 and m3, it is established that m1=m2>m3.

10. A current sensor, comprising:
a first MI sensor part and a second MI sensor part arranged to apply magnetic fields induced by a measurement target current in mutually opposite directions;
a sample/hold part configured to receive a differential input between a first sensor signal generated by the first MI sensor part and a second sensor signal generated by the second MI sensor part to generate a sample/hold signal; and
an amplifier part configured to amplify the sample/hold signal to generate an output signal.

11. A current sensor, comprising:
a first MI sensor part and a second MI sensor part arranged to apply magnetic fields induced by a measurement target current in mutually opposite directions;
a first sample/hold part configured to receive a first sensor signal generated by the first MI sensor part to generate a first sample/hold signal;
a second sample/hold part configured to receive a second sensor signal generated by the second MI sensor part to generate a second sample/hold signal;
a first amplifier part configured to amplify the first sample/hold signal or an amplified signal of the first sample/hold signal with a first gain to generate a first amplified signal;
a second amplifier part configured to amplify the second sample/hold signal or an amplified signal of the second sample/hold signal with a second gain to generate a second amplified signal;
a subtraction part configured to subtract the second amplified signal from the first amplified signal to generate an output signal; and
a gain adjusting part configured to adjust the first gain and the second gain to correct a difference in sensitivity of the first MI sensor part and the second MI sensor part.

12. The current sensor of claim 11, wherein when the sensitivity of the first MI sensor part and the sensitivity of the second MI sensor part are α and β, respectively, and the first gain and the second gain are X and Y, respectively, it is established that X/Y=β/α.

13. The current sensor of claim 12, wherein it is established that X=1/α and Y=1/β.

14. A measurement target system, comprising:
a primary conductor; and
the current sensor of claim 1, configured to measure a measurement target current flowing through the primary conductor while securing insulation from the primary conductor.

15. The system of claim 14, wherein the primary conductor includes an outward path part and a return path part installed such that the measurement target current flows in mutually opposite directions, and
he current sensor includes a sensor device installed at a position equidistant from the outward path part and the return path part to detect magnetic fields induced by the measurement target current.
